(19) United States
(12) Patent Application Publication
(10) Pub. No.: US 2025/0334621 A1
(43) Pub. Date: Oct. 30, 2025

(54) Refractive Index Measurements of Very Low Reflection Coefficient Materials at Millimeter Wavelengths

(71) Applicant: The Government of the United States of America, as represented by the Secretary of Homeland Security, Washington, DC (US)

(72) Inventors: Peter Roland Smith, Westfield, NJ (US); James Christopher Weatherall, Linwood, NJ (US); Jeffrey Brian Barber, Vineland, NJ (US)

(73) Assignee: The Government of the United States of America, as represented by the Secretary of Homeland Security, Washington, DC (US)

(21) Appl. No.: 19/189,466

(22) Filed: Apr. 25, 2025

Related U.S. Application Data
(60) Provisional application No. 63/638,709, filed on Apr. 25, 2024.

(51) Int. Cl. G01R 27/28; G01R 35/00

(52) U.S. Cl. CPC G01R 27/28; G01R 35/005

(57) ABSTRACT

Examples are directed toward a system and method relating to extracting a complex permittivity of a material. For example, a system includes a Vector Network Analyzer (VNA) that performs a first reflection measurement for a front interface of the material, and obtains first time-domain data by applying an inverse fast Fourier transform (IFFT) to the first reflection measurement. The VNA performs a second reflection measurement for a back interface of a material, and obtains second time-domain data by applying the IFFT to the second reflection measurement. The system performs a set of two measurements, including the measurements set forth above at the interfaces with the material, and similar measurements at the locations of the interfaces but without the material (e.g., empty measurements). A processor determines a real part of a refractive index of the material based on velocity, and determines an imaginary part of the refractive index of the material based on energy loss.

### CROSS-REFERENCE TO RELATED APPLICATIONS

This nonprovisional application claims the benefit of priority to U.S. Provisional Application No. 63/638,709, entitled “Refractive Index Measurements of Very Low Reflection Coefficient Materials at Millimeter Wavelengths,” filed Apr. 25, 2024, the content of which is incorporated herein by reference in its entirety.

### STATEMENT OF GOVERNMENT INTEREST

The claimed subject matter was made by one or more employees of the United States Department of Homeland Security in the performance of official duties. The Government has certain rights in the invention.

### FIELD

The present subject matter relates generally to the field of imaging, and more specifically to the field of screening systems.

### BACKGROUND

Structural materials that are virtually invisible during millimeter-wave imaging are needed for applications in testing Advanced Imaging Technology (AIT) screening systems, for example by supporting image-quality test objects. Laboratory measurement of the electrical permittivity of candidate materials at the frequency of the imaging system can appraise their suitability as very low-reflective materials, but measurement is challenging because the ideal material has a real component of permittivity near unity and nearly zero energy absorption.

### SUMMARY

Embodiments provide a system that extracts a complex permittivity of a material. The system includes a Vector Network Analyzer (VNA) that performs a set 1 of reflection measurements over a finite frequency-bandwidth of a free-space reflection coefficient S11 for a front interface of the empty (no material) and the material, with the Measurement Reference Plane (MRP) calibrated at that front interface, the front interface being between the material and air. The VNA obtains set 1 time-domain data by applying an inverse fast Fourier transform (IFFT) to the set 1 reflection measurements, each data in the set presenting as peaks in the time domain. The VNA performs a set 2 of reflection measurements over a finite frequency-bandwidth of a free-space reflection coefficient S11 for a back interface of an empty and a material, with the MRP calibrated at that back interface, the back interface being between the material and metal. The VNA obtains set 2 time-domain data by applying the IFFT to the set 2 reflection measurements, each data in the set presenting as a peak in the time domain. A processor determines a real part of a refractive index of the material based on velocity, by either 1) calculating a temporal difference between the locations in time of the peaks of set 2 time domain data at the back MRP, or 2) by calculating a ratio between the locations in time of the peaks at the back interface of set 1 time domain data which has the MRP at the front interface, independent of energy of the peaks. The processor is configured to determine an imaginary part of the refractive index of the material based on energy loss, by calculating an energy deficit in total reflected energy of the peak of the empty of set 2 time domain data at the back MRP, and the peak of the material of set 2 time domain data at the back MRP, also taking into account the reflected energies at the front interface MRP of the empty and material in set 1 time domain data, independent of locations of the peaks in time.

In an example embodiment, a method for extracting a complex permittivity of a material includes performing, using a Vector Network Analyzer (VNA), a set 1 of reflection measurements over a finite frequency-bandwidth of a free-space reflection coefficient S11 for a front interface of the empty (no material) and the material, with the Measurement Reference Plane (MRP) calibrated at that front interface, the front interface being between the material and air. The VNA obtains set 1 time-domain data by applying an inverse fast Fourier transform (IFFT) to the set 1 reflection measurements, each data in the set presenting as peaks in the time domain. The VNA performs a set 2 of reflection measurements over a finite frequency-bandwidth of a free-space reflection coefficient S11 for a back interface of an empty and a material, with the MRP calibrated at that back interface, the back interface being between the material and metal. The VNA obtains set 2 time-domain data by applying the IFFT to the set 2 reflection measurements, each data in the set presenting as a peak in the time domain. A processor determines a real part of a refractive index of the material based on velocity, by either 1) calculating a temporal difference between the locations in time of the peaks of set 2 time domain data at the back MRP, or 2) by calculating a ratio between the locations in time of the peaks at the back interface of set 1 time domain data which has the MRP at the front interface, independent of energy of the peaks. The processor determines an imaginary part of the refractive index of the material based on energy loss, by calculating an energy deficit in total reflected energy of the peak of the empty of set 2 time domain data at the back MRP, and the peak of the material of set 2 time domain data at the back MRP, also taking into account the reflected energies at the front interface MRP of the empty and material in set 1 time domain data, independent of locations of the peaks in time. The processor outputs an indication of the real part and the imaginary part of the refractive index of the material.

Other features and aspects will become apparent from the following detailed description, which taken in conjunction with the accompanying drawings illustrate, by way of example, the features in accordance with embodiments of the claimed subject matter. This summary is not intended to identify key or essential features of the claimed subject matter, nor is it intended to limit the scope of the claimed subject matter, which is defined solely by the claims attached hereto.

### BRIEF DESCRIPTION OF THE DRAWINGS

One or more example embodiments of the subject matter are described in detail with reference to the following drawings. These drawings are provided to facilitate understanding of the present subject matter and should not be read as limiting the breadth, scope, or applicability thereof. For purposes of clarity and ease of illustration, these drawings are not necessarily made to scale.

FIG. 1 illustrates a measurement system according to an embodiment.

FIG. 2 illustrates a chart of round trip time of flight with the measurement reference plane (MRP) at a front surface of the material according to an embodiment.

FIG. 3 illustrates a chart of round trip time of flight with the measurement reference plane (MRP) at a back surface of the material according to an embodiment.

FIG. 4 (a) illustrates a first chart of a wave profile as a function of time for no material according to an embodiment.

FIG. 4 (b) illustrates a second chart of a wave profile as a function of time for no material according to an embodiment.

FIG. 4 (c) illustrates a third chart of a wave profile as a function of time for the material according to an embodiment.

FIG. 4 (d) illustrates a fourth chart of a wave profile as a function of time for the material according to an embodiment.

FIG. 5 illustrates a flowchart to determine a refractive index according to an embodiment.

These drawings are not intended to be exhaustive or to limit the subject matter to the precise form(s) disclosed. It should be understood that the present subject matter can be practiced with modification and alteration, and that the subject matter is limited only by the claims and the equivalents thereof.

### DETAILED DESCRIPTION

A method is described based on temporal features in wave packet propagation using dual calibrations for front and back interfaces. Measurements of different foam materials are demonstrated.

### INTRODUCTION

Propagation loss is due to the 1/r reduction of the electric field as the wave propagates-even in free space. The (additional) energy lost in passing through a material is the energy absorbed by the material. The measurement methods described herein can measure at the back surface. The measurements with the material and without the material both include the same 1/r propagation loss. However, the measurement through the material also includes the energy lost to absorption in the material. Subtracting the energies (not the arrival times, which are separate) yields the energy absorbed in the material. The methods can correct for this by the energy reflected off the front surface of the material that is not available to travel through the material and be absorbed. That correction is made by measuring the reflection at the front surface.

Electromagnetic reflection one port measurements can be made by placing a measurement reference plane at a front surface of a material being measured. However, techniques described herein enable the system to compensate and allow use of the measurement reference plane located at a back surface or within the material. Techniques can make use of measurements involving a reflection at the front surface of the material, and propagation through the material to the metal plate at the back, which then reflects the wave back through the material to the material/air interface and back to the antenna. Techniques described herein compensate for the electric field's weakening 1/r dependency, by calculating and compensating for the propagation through the material. The techniques obtain the information at the interface between the material and air, and also at the interface between the material and the metal. The techniques allow separating the back surface reflection from the front surface reflection, enabling measurements without needing to know a thickness of the material because the techniques can eliminate material thickness as a factor. Set forth below are new free-space measurement techniques that use multiple calibrations. This enables the material losses to be measured by summing reflected energy from the front surface and the back surface, and computing how much energy has been lost in the material.

The use of two calibrations is described, to get the accurate measurements. The use of multiple calibrations is supported. This allows for consideration of measurement propagation losses (the 1/r fall-off of the electromagnetic field), e.g., when a relatively thick sample material is near to the antenna. Notably, the techniques described herein enable measurement of energy loss in reflection, enable dual calibration (instead of beam focusing), and exploit a network analyzer time domain function (which can be used generally to analyze frequency signals). Making use of the time delay between signals enables higher precision measurements compared to using the amplitude differences. For example, an amplitude-based approach might be limited by ±1%, in contrast to using the time domain enabling much more accurate measurements to, e.g., 1/10 of a picosecond. Accordingly, the techniques described herein can be used to contribute to, e.g., how IEEE image quality is assessed for metal test patterns that are mounted in imaging systems by using materials to mount the metal test patterns that will not substantially interfere with measurements (e.g., quantifying the ‘invisibility factor’ of those materials). These techniques also can be used to advance the construction of waveguides, to advance the propagation of waves, and for other applications.

The IEEE N 42.59 test standard pertains to measuring the imaging performance of active millimeter wave systems for security screening of humans. The N 42.59 test standard also defines test objects for evaluating the imaging performance of active millimeter wave Advanced Imaging Technology (AIT) systems for security screening. Very low reflectivity materials can be used to support these test objects so as not to interfere with the extraction of performance metrics. The material properties characterizing reflectivity are the complex permittivity, or the corresponding refractive index. (The relationship between permittivity c and refractive index n is ∈/∈₀=n², ∈₀ being the permittivity of free space.) The N 42.59 standard provides an informative specification for structural materials to have permittivity of real part between 1.01 and 1.08 and an imaginary part less than 0.01, and identifies closed cell cross-linked polyethylene foam as a suitable material based on its low reflectivity at millimeter wavelengths. A motivation of this work is to establish the suitability of various foam materials for application of the IEEE standard to screening systems operating in E-band (60-90 GHz).

Measurements are performed with a free-space measurement system using reflection from metal-backed materials. Previous characterizations of foam materials used for structural support of targets in radar cross section measurements are based on back-scattering and without reporting dielectric loss. Similarly, some optical applications only require accurate measure of the real permittivity. Other characterizations of low loss foams have been in THz frequency for dielectric waveguides and dichroic filtering. In MMW, applications have been studied for dielectric Fresnel and Mikaelian lenses and coax cables, but these have not been for the lowest permittivity foams. Porous low-permittivity and low-loss materials for telecommunication devices at THz frequencies require knowledge of the complex permittivity, and have been studied using time-domain spectroscopy (TDS). The dielectric loss of various types of foams are well-studied at THz frequencies, but because absorption is proportional to frequency it is more challenging to detect the imaginary component of the permittivity at millimeter-wave (MMW) frequencies where the loss is very small: consider, for example, that at 4 THz the extinction rate of a low density plastic foam (polystyrene) is measured to be α˜1.5 cm⁻¹, while the permittivity of a similar low density foam (polyethylene) measured in X-band (11.2 GHz) indicates a loss rate of a˜0.004 cm⁻¹. Measurements of low dielectric loss materials at MMW frequencies can be accomplished with resonant techniques using split-ring resonators, waveguide resonators, and microstrip ring resonators. However, a notable difficulty with resonant methods is that the samples are small, and sample preparation and consistency becomes a factor for measurement. In free space, as shown herein, the thickness of the sample can be large, so the loss has larger signal-to-noise factor for the detection of the imaginary part of the permittivity. An interesting aspect of the methods described herein is performing the reflection measurement in the time domain using a wave optics model to extract the permittivity. This extends the TDS method used in THz to lower MMW frequency. The use of time-domain techniques in MMW measurement are often used for time-gating the signal to eliminate spurious reflections; the signal in the time-domain has also been applied to calibration. Examples of permittivity measurement in the time domain in MMW include the use of a wavelet generator and a wideband leaky lens antenna to generate the time-pulse for transmission measurement; another is a method to isolate the front surface reflection to add data to the solution of the inverse problem. Pulse timing data is useful to characterize the low reflective materials because the accuracy of the measurement of the real permittivity using standard transmission/reflection methods is on the order of the uncertainty in the reflection S-parameter, ΔS₁₁/S₁₁ while in the time domain the accuracy is on the order of Δtₘₐₜ/tₐᵢᵣ, where Δtₘₐₜ is the time delay relative to the time tₐᵢᵣ for the signal to cross a thickness in air. Precision in timing to measure the speed of light in the material can be improved by increasing the thickness of the sample. An analytic framework to evaluate losses due to dielectric absorption notwithstanding multiple reflections at the material interfaces is provided herein. Because the sample is relatively large, the propagation loss (or 1/r due to the proximity of the antenna) uses a dual calibration technique (which seems unique to our work) to accomplish the measurement of loss in reflection. The dual calibration also enables measurement without collimating the beam (e.g., measurement without using a RAM aperture).

The complex refractive index is obtained from time-domain data generated from the inverse fast Fourier transform (IFFT) of the free-space reflection coefficient (S₁₁) measured over a finite frequency-bandwidth. The material under test (MUT) is a thick slab having a front interface with air and back interface with metal. Reflections from the two interfaces present as peaks in the time domain. The real part of the refractive index is associated with velocity and the temporal relationship between peaks, but not dependent on the energy of the peaks themselves. The imaginary part of the refractive index is associated with the energy deficit in the total reflected energy of the peaks, but not dependent on their location in time. In the method and analysis, the real and imaginary parts of the refractive index are shown to be calculated independently from the respective measures of propagation velocity and energy loss.

### Materials and Methods

### Instrumentation

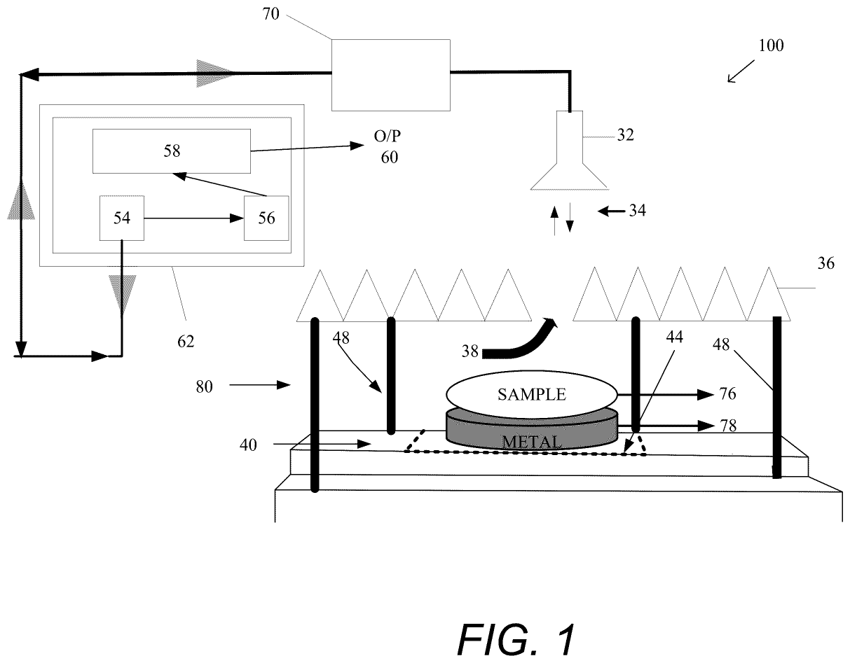

FIG. 1 illustrates an embodiment of a measurement system 100 to measure the materials in free space over frequencies of 60-90 GHz (E band). The illustrated measurement system 100 includes a Keysight Technologies PNA E8364C (VNA) 62 with an OML, Inc., V12VNA2-T/R millimeter wave frequency extender 70 to operate in E band. A Custom Microwave, Inc., Model RCH012R, conical horn antenna 32 is connected by waveguide to the frequency extender 70. An aperture 38 in a layer of radar absorbing material (RAM) 36 is used to reduce the radiated beam width. The absorbing material is RAM IS-005A manufactured by TDK RF Solutions, Inc.

In another embodiment, the measurement system 100 comprises a transceiving antenna 32 with a transceiving axis 34, a source of electromagnetic radiation 54, a receiver 56, a processor 58 providing output 60 and a staging area 80. Staging area 80 includes a measurement region 44, a vertical translation stage 40, and posts 48 supporting the RAM 36 with an aperture 38. The source of electromagnetic radiation 54, the receiver 56, and the processor 58 may be combined into a vector network analyzer 62. The vertical translation stage 40 is below the sample holder plate 78. The processor 58 also can generate and output results to a display, printer, communication, or the like. The processor 58 can also provide inverse fast Fourier transform (IFFT) time domain data of the measured frequency domain data, or this functionality can be provided by an additional processor, for example a computer. In an embodiment, the time domain data are obtained by using an option, or application, provided by the Keysight model PNA E8364C VNA, to convert the frequency domain reflection coefficient data. In another embodiment, the IFFT can be determined external to the VNA.

The transceiving antenna 32 is a combined transmitter and receiver antenna (transceiver antenna) configured to transmit and receive electromagnetic radiation along a transceiving axis 34. The transceiving antenna 32 is typically mounted (not shown) such that the transceiving axis thereof 34 is substantially orthogonal to and substantially aligned with a test sample (not shown) to be measured within a measurement region 44. Transceiving antennas suitable for use with the present measurement systems include e.g., a ridged antenna, a conical horn etc., such as a Model RCH012R, Custom Microwave, Inc., Longmont, CO.

As further shown in FIG. 1, radar absorbing material (RAM) 36, such as a Model TDK IS-005A RAM, TDK RF Solutions, Inc., Cedar Parker, TX, is positioned between the transceiver antenna 32 and the measurement region 44 of the transceiver antenna. The RAM 36, which comprises an aperture 38, may be supported by posts 48 set upright in a stage 40, such as a vertical translation stage, e.g., Model MLJ 050 from Thorlabs, Inc., Newton, NJ. The aperture 38 of the RAM 36 is arranged such that it is substantially orthogonal to and substantially aligned with the transceiving axis 34.

Aperture 38, may be of any shape and/or size, such as a geometric shape, e.g., a circle, triangle, rectangle, square etc. In some embodiments, the aperture is a square, each side of the square aperture having a length ranging from five to 10 wavelengths. In some embodiments, the aperture has an area ranging from 25 mm² to 10,000 mm², such as 2500 mm² to 5000 mm², such as 250 mm² to 500 mm², such as 25 mm² to 100 mm². At E band frequencies, the square aperture in the measurement system was five wavelengths or greater on a side. Estimates of Fraunhofer diffraction from the aperture indicated that less than 5% of the incident field was diffracted. The aperture also significantly reduced the radiated power on the test sample, but there was sufficient dynamic range in the VNA to compensate for this. After calibration, the dynamic range was >92 dB, which was limited by the RAM used as a calibration standard, and sufficient to provide four decimal places of accuracy, which enables the precision to achieve the values of Table 3.

The measurement region 44 may be located in the radiating near field (Fresnel Field) or the far-field (Fraunhofer Field) of the transceiver 32. As used herein, a field, which is located very near to a transceiver is termed the “reactive near field.” Radiation is not predominant in this field. In contrast, radiation predominates in the region next to the reactive near field, i.e., the “radiating near field” or “Fresnel field.” In the Fresnel field, the angular field distribution depends on the physical distance from the transceiver. The far-field, or Fraunhofer region, which is dominated by radiated fields, is located next to the Fresnel field. In this region, the radiation pattern does not change shape with distance from the antenna.

In some embodiments, the far-field may be defined as Far-field≥2D²/λ where D is the largest dimension of the radiator (or the diameter of the transceiver) and A is the wavelength of the electromagnetic wave, i.e., λ is the speed of light/signal frequency.

Typically, the measurement region 44 is located in the far-field of the transceiver antenna 32. In some embodiments, the location of the measurement region 44 relative to the transceiver antenna 32 may be described in terms of numerical ranges: for example, the distance of the measurement region from the transceiver antenna may be in the range of 0.1-1.2 meters or in the range of 0.12 to 0.3 meters, such as 0.16 to 0.24 meters. The skilled person would understand that such range is typically measured from the emitting/receiving aperture of the transceiver antenna 32, e.g. from the position at which free-space propagation of the electromagnetic radiation occurs.

Transceiving antenna 32 is configured to be coupled to a source of electromagnetic radiation 54 and a receiver 56 adapted to receive and measure electromagnetic radiation reflected from a test sample (not shown). The electromagnetic radiation source 54 may be provided by a signal generator, e.g., a radio frequency (RF) signal generator, a microwave signal generator, a microwave signal generator coupled with an external waveguide source module, etc.

In some embodiments, the electromagnetic radiation has a frequency in the range of 1-1000 GHz, such as 60 GHz to 500 GHz. For example, in some embodiments, the electromagnetic radiation has a frequency range in the V band (50 to 75 GHZ, wavelength range 4.0 to 6.0 millimeters (mm)) or greater, e.g., the E band (60 to 90 GHz, wavelength range 5.0-3.33 mm), W band (75 to 110 GHz, wavelength range 2.7 mm to 4.0 mm), F band (90 to 140 GHz, wavelength range 2.1-3.3 mm), D band (110 GHz to 170 GHz, 1.8-2.7 mm), etc. As illustrated by example, the electromagnetic radiation has a frequency in the E band.

Receiver 56 is adapted to receive and to measure electromagnetic radiation reflected from the test sample (not shown) via the transceiver antenna 32. In some embodiments, the measurement output from the receiver 56 is input to a processor 58, which is configured to determine, e.g., a reflection coefficient, a permittivity and/or other parameters of a test sample (not shown). The processor 58 has an output 60 for providing, e.g., a determination of a reflection coefficient and/or a permittivity of a test sample (not shown). Typically, the electromagnetic radiation source 54, the receiver 56 and the processor 58 are combined within a VNA 62, for example, Model E8364C PNA, Keysight Technologies Inc., Santa Rosa, CA.

The electromagnetic source 54 of the measurement system 100, which is part of the VNA 62, is also depicted as connected to a millimeter wave frequency extender 70, such as a Model V12VNA2-T/R Millimeter Wave Frequency Extender, OM L, Inc., Morgan Hill, CA. The electromagnetic source 54, the receiver 56, and the processor 58 can also be separated while providing the same functionality of the VNA. The millimeter wave frequency extender 70 can also be constructed from separate components; a millimeter wave source and a frequency multiplier. The millimeter wave source may further comprise an amplifier. Millimeter wave frequency extenders, frequency multipliers and optional amplifiers may be desirable for the generation of frequencies in, e.g., the E band or greater.

The measurement system 100 of FIG. 1 also depicts a test sample 76 in measurement region 44. In this embodiment, test sample 76 is placed on a conducting substrate 78, such as a metal conducting substrate. The test sample and conducting substrate are placed into the measurement region 44 located on stage 40. A radiated beam passes through the aperture 38 in the RAM 36 to the test sample 76 being measured. The reflected signal passes back through the aperture 38 to the transceiver antenna 32, where it is collected and passed back to the e.g., a vector network analyzer 62 for reflection coefficient measurement.

The present method also comprises illuminating the test sample 76 with electromagnetic radiation over a predetermined frequency range. As used herein, a “predetermined frequency range” includes any frequency range including, e.g., frequencies of radio waves, frequencies of microwaves and/or frequencies of millimeter waves. A “predetermined frequency range” as used herein is contemplated to include those frequencies ranging from 1-1000 GHz, such as in any of the E band (60 to 90 GHz), W band (75 to 110 GHz), F band (90 to 140 GHz), D band (110 GHz to 170 GHz), G band (140 to 220 GHz) and Y band (325 to 500 GHz), e.g., any frequency band greater than V band (50 to 75 GHz).

The present method of measuring a reflection coefficient of a test sample 76 also comprises determining the reflection coefficient of the test sample based on the reflected electromagnetic radiation. The receiver 56 can be used to measure the magnitude and phase of the electromagnetic radiation reflected from a test sample 76 at a desired frequency. In some embodiments, the processor 58 of a VNA 62, for example, may output 60 a corrected reflection coefficient using well known error correction models after the measurement system is conventionally calibrated as known in the art and described, for example, in Dunsmore, Joel P. “Calibration and Vector Error Correction.” Handbook of Microwave Component Measurements, John Wiley & Sons, 2012, pp. 124-210, which is herein incorporated by reference in its entirety. In some embodiments the measured reflection coefficient is an S₁₁ reflection coefficient, which is a raw or uncorrected S₁₁ reflection coefficient. In other embodiments, the measured reflection coefficient is an actual S₁₁ reflection coefficient after error correction as known in the art or as described herein using the present method of obtaining error correction.

The present disclosure is also directed to a method of obtaining error correction for a reflection coefficient measurement system, e.g., a measurement system that includes a VNA.

Accordingly, the present method may be used to remove systematic errors from a measurement system. For example, in some embodiments, the measurement system may have three systematic errors, i.e., directivity, reflection tracking and source match. Correction values of these systematic errors may be determined using the present method, which, in turn, may be used to obtain an error correction. The error correction may then be used to remove errors from subsequent test sample measurements.

Materials 76 to be measured were placed on a 12×12 in (30.5×30.5 cm) aluminum plate 78, and the assembly was set atop a breadboard attached to a Thorlabs M odel MLJ 050 motorized vertical translation stage 40 with a 0.1 μm resolution. The VNA 62 was calibrated using the 12×12 in aluminum plate for the short and offset short calibration standards, and a similarly-sized piece of RAM for the sample 76, also referred to as load. Immediately after calibration, the load (e.g., sample 76) and short (e.g., metal plate 78) were remeasured, establishing the system dynamic range at 92.7 dB. For comparative measurements without the material, the material is removed leaving the aluminum plate in place. The one port S₁₁ reflection coefficient frequency spectrum is transformed to the time domain locally in the VNA using Keysight's time domain option. The transformation was chosen to provide a 300 picosecond (ps) wide window around the reflections from the front and back foam-material surfaces at 0.1 ps intervals. The time domain reflection coefficient magnitude resolution, based on the maximum value of the load reflection in the temporal band, is 2.38×10⁻⁵.

The RAM 36 and aperture 38 are optional, and measurements can be performed with the RAM 36 removed. In the illustrated embodiment, a method of measuring a reflection coefficient of a test sample 76 or a conducting material 78 includes arranging the RAM 36 between the transceiver antenna 32 and measurement region 44. As noted herein, the RAM 36 includes an aperture 38 positioned substantially orthogonal to and substantially aligned with the transceiving axis 34 of the transceiver antenna 32. In some embodiments, the use of an aperture 38 in the RAM 36 to illuminate the test sample 76 allows for a reduction in beam size, thus permitting the reflection coefficient measurements of smaller samples. In other embodiments, the RAM aperture 38 reduces the variation in the radio frequency (RF) radiation that illuminates a test sample by e.g., absorbing the antenna side lobes and any reflections from the surrounding environment in comparison to the RF radiation variation and reflections in the absence of the RAM aperture 38. The RAM aperture 38 may be any shape or size as described herein. The RAM 36 and aperture 38 may allow for less than 5% diffraction of the incident field. Further, in some embodiments, the aperture 38 the RAM 36 reduces the beam size, thus reducing test sample 76 lateral movement sensitivity and allowing for the use of smaller test samples. The aperture 38 may also reduce the amount of radiated power on a test sample 76. Nevertheless, in some embodiments, such as those methods that include a vector network analyzer 62, the dynamic range of the VNA 62 can compensate for any reduction in radiated power.

### Low Reflectivity Foams

Measurements were performed on cross-linked polyethylene (XL PE) and closed cell polystyrene (CCPS) foams. The materials were manufactured with nominal thickness of 3 in (7.52 cm) and cut to the cross sectional size 12×12 in. The XLPE had density 3 pounds per cubic feet (PCF), and two samples CCPS were used having densities 3 PCF and 1 PCF. The physical data are summarized in Table 1.

TABLE 1
Structural Foam Parameters

| Material | Mass Density | Thickness | |
|---|---|---|---|
| XLPE (3 lb) | 48 kg/m³ | 7.481 ± 0.005 | cm |
| CCPS (1 lb) | 16 kg/m³ | 7.55 ± 0.03 | cm |
| CCPS (3 lb) | 48 kg/m³ | 7.59 ± 0.04 | cm |

### Measurement Reference Planes

The complex refractive index can be measured by time reflection data for materials that are thick relative to the band pass response resolution of the system, which allows the reflections at the front and back surfaces to be separated in the time domain. Although the target is in the antenna far-field, the target thickness is not much less than its distance from the antenna, so compensation must be made for the propagation loss due to the 1/r field dependence. This is accomplished with multiple calibrations to perform measurements at front and back surfaces.

Without being limited by theory, it is believed that test samples measured at the measurement reference plane yield the reflection coefficient of the test sample directly. If the measurement reference plane is defined elsewhere, the measured reflection coefficient is a measurement of the test sample and the material between it and the measurement reference plane. To obtain only the test sample reflection coefficient, either the measurement reference plane can be mathematically translated to the test sample prior to measurement, or the data can be translated to the measurement reference plane, after measurement, by the appropriate phase offset and attenuation. See e.g., Hammler, J., Gallant, A. J., and Balocco, C., “Free-Space Permittivity Measurement at Terahertz Frequencies With a Vector Network Analyzer,” IEEE Transactions on Terahertz Science and Technology, 6(6), 817-823 (2016), which is herein incorporated by reference in its entirety. In some embodiments, defining the measurement reference plane at the top surface of the material eliminates this issue, allowing the reflection coefficient of the test sample to be measured directly.

The two measurement reference planes (MRP) are established during two different VNA calibrations and are applied depending on whether the measurement is associated with the reflection at the back surface or the reflection from the front surface of the material. The first calibration is performed to provide the MRP at the front surface of the material, which is located by moving the translation stage until the reflection signal peak is within 0.1 ps to 0.2 ps of the reflection peak maximum (t=0). At different locations across the material or with varied materials, the sample is raised or lowered to maintain the MRP at the front surface. To obtain an accurate measure of the reflection from the back surface, a second calibration is used with the MRP at the surface of the backing metal plate. The back surface MRP is established once during calibration for all subsequent measurements.

### Real Part of Refractive Index

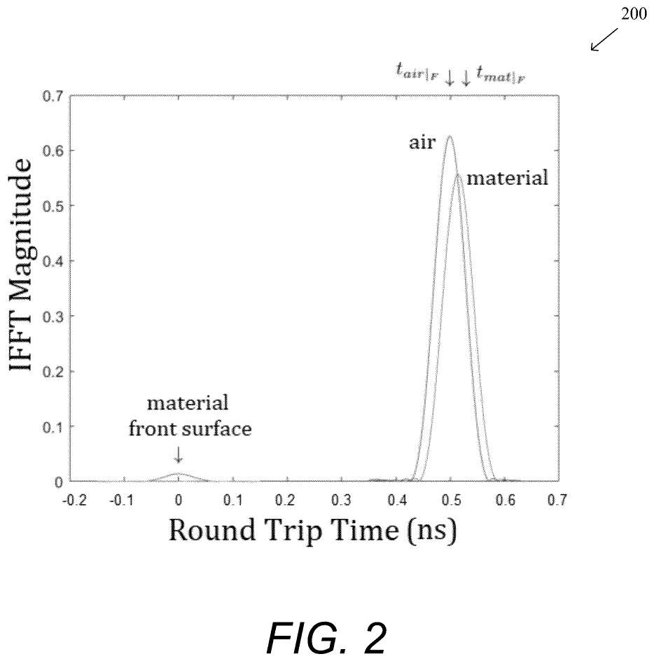

The real part of the refractive index is calculated based on the times-of-flight of the signals with and without foam materials. An example chart 200 is shown in FIG. 2, where the signal from the back surface is delayed in the material relative to the signal in air because the wave propagation speed in the material, c/nᵣ, is less than the speed of light c in air depending on the real part of the refractive index, nᵣ. Because the MRP is at the front surface (note the small reflection at t=0 for the XLPE foam), the times measured at the peaks are the time-of-flight of the reflected signal through the material, which are t_{mat|F}=2Lnᵣ/c and t_{air|F}=2L/c, respectively. The notation F denotes the measurement has the MRP at the front surface; B will be used to denote measurement with MRP at the back surface. The thickness L is the same in both cases, so the equations can be combined to solve for real part of the refractive index:

$${n}_{r} = \frac{{t}_{{mat \vert}_{F}}}{{t}_{{air \vert}_{F}}} [ MRP front ] . \qquad ( 1 )$$

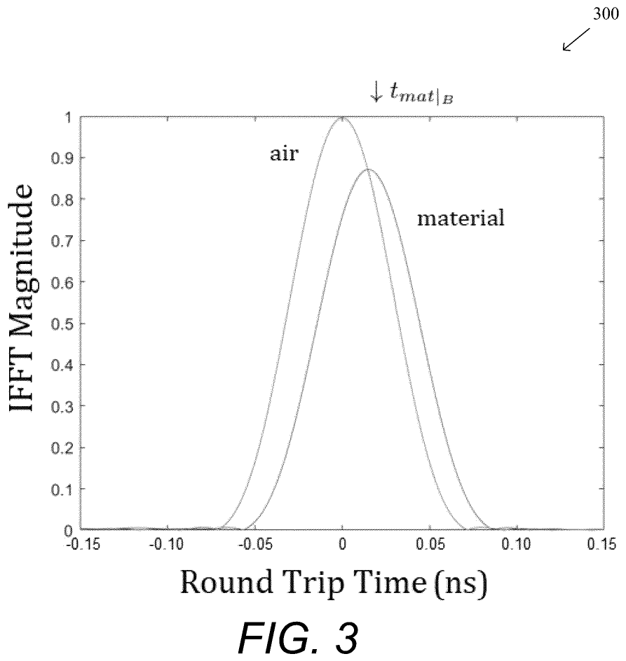

Alternatively, the index of refraction can be derived from the time delay Δt=tₘₐₜ−tₐᵢᵣ in the signal peaks with and without the material because the thickness L is known. Applying the MRP at the metal back surface is useful for this case, because the time delay is simply the arrival time t_{mat|B} of the intensity peak with the material in place, as shown in chart 300 of FIG. 3. The real part of the refractive index can be computed by

$${n}_{r} - 1 = \frac{c {t}_{{mat \vert}_{B}}}{2 L} [ MRP back ] . \qquad ( 2 )$$

Note that the times in Eqs. (1) and (2) are the peak reflections (i.e., maximum return from the metal) for the corresponding MRP. It will be apparent in the Results section below that Eq. (2) provides the more accurate result for nᵣ; this can be demonstrated from propagation of error in the measurement based on time difference versus the time ratio.

### Imaginary Part of Refractive Index

The imaginary part of the refractive index is inferred from the energy loss observed when the material is placed in the beam. The intensity magnitude of a plane wave traversing a distance z in a medium of refractive index n falls off as e^{-αz}, where the absorption constant α is found from the imaginary part of the wavenumber k=β+iα/2. By definition of wavenumber k=nω/c, the absorption constant is α/2=nᵢω/c.

The arrival of a signal after propagation through a dispersive medium is a well-studied problem in physics. When the pulse is modeled as a Gaussian function of width Δω centered at frequency ω₀, the energy absorbed in the pulse during propagation through path length 2L is given by

$$Δ W = - W [ 1 - {e}^{- 2 {n}_{i} ( 2 L {ω}_{0} / c )} ] , \qquad ( 3 )$$

where W is the initial wavepacket energy. A term of order

$${n}_{i}^{2}$$

is left out of the exponential. Assuming the exponential in the loss term is small, the energy equation can be written ΔW=−ηW, where the loss factor is

$$η = 2 {n}_{i} ( \frac{2 L {ω}_{0}}{c} ) . \qquad ( 4 )$$

The energy integrals are done in the time domain in two parts on intervals±0.15 ns at the front and back surface reference plane using the respective MRP:

$${W}_{F} = {{\int }_{F}}_{- 0.15 n s}^{0.15 n s} {\vert {S}_{11} ( t ) \vert}^{2} dt , \qquad ( 5 )$$

$${W}_{B} = {{\int }_{B}}_{- 0.15 n s}^{0.15 n s} {\vert {S}_{11} ( t ) \vert}^{2} dt . \qquad ( 6 )$$

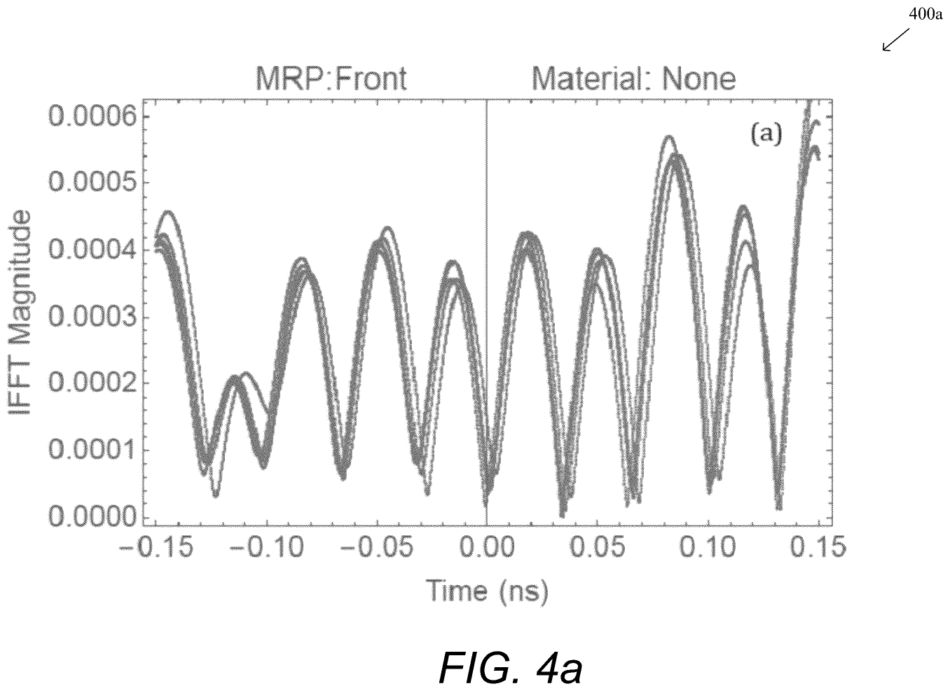

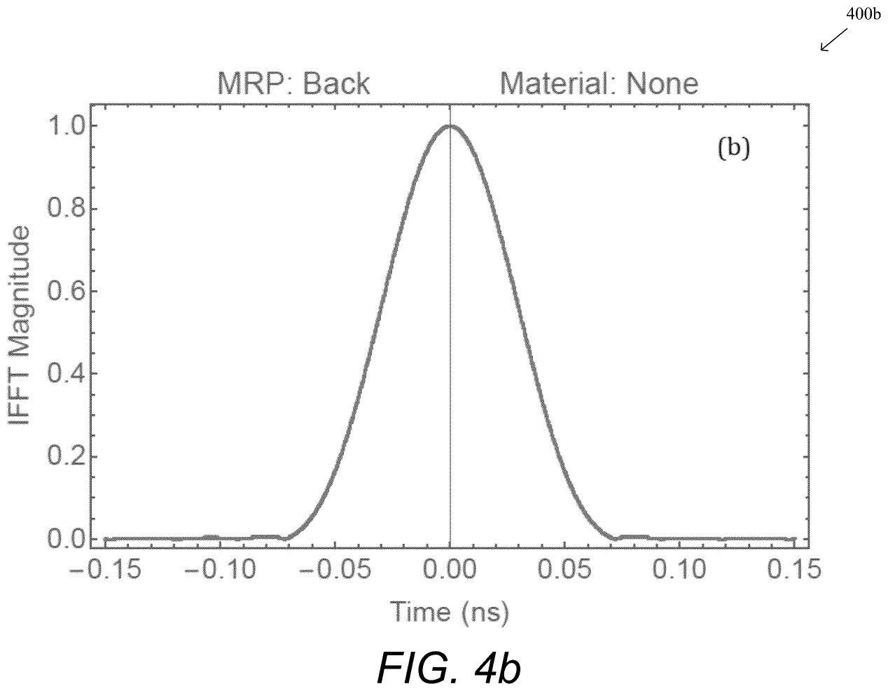

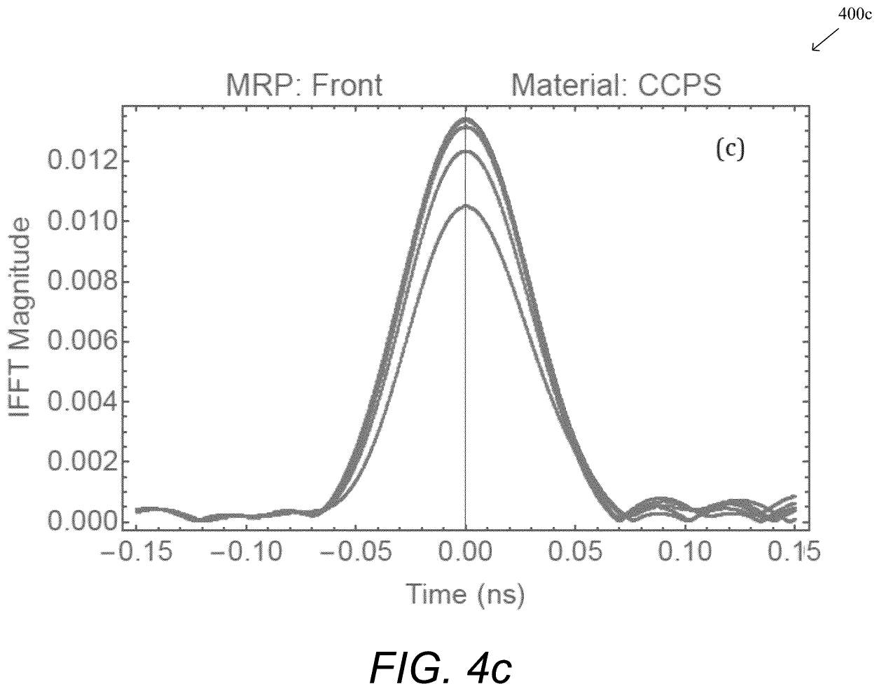

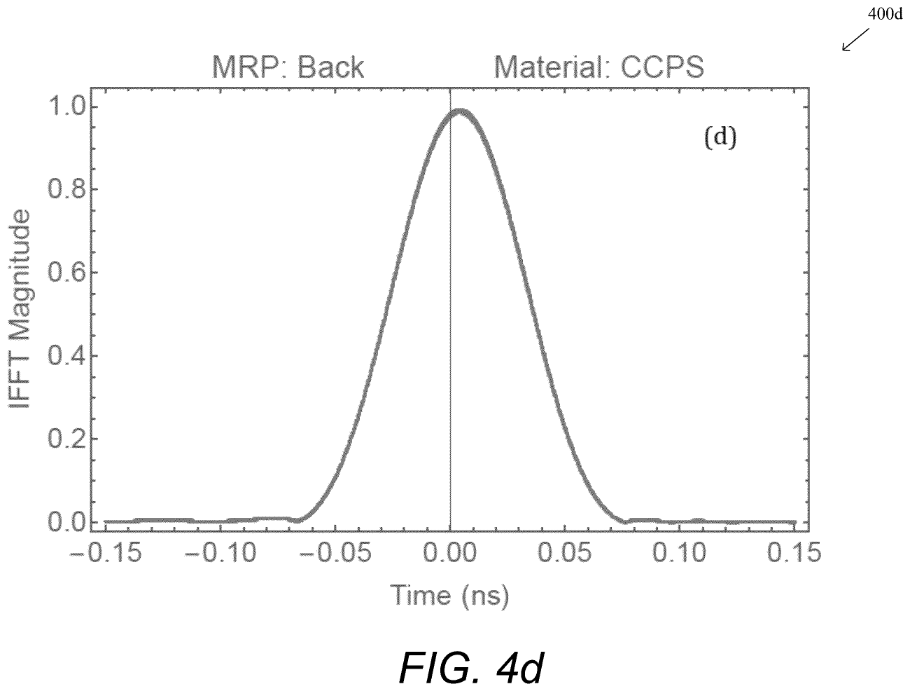

The reflection magnitudes |S₁₁| for empty space and for the polystyrene foam are illustrated in chart 400a of FIG. 4 (a), chart 400b of FIG. 4 (b), chart 400c of FIG. 4 (c), and chart 400d of FIG. 4 (d). The energy budget for the back plate reflection is summarized in Table 2, where the circumflex indicates that the quantity is normalized to the input “energy” for air, W=W_{F}+W_{B}=0.0485 ns. Based on the energy budget, the loss factor in the material can be evaluated:

$$η = 1 - {\hat{W}}_{F} - {\hat{W}}_{B} - {\hat{W}}_{B} {\hat{W}}_{F} + o ( {\hat{W}}_{F}^{2} ) \qquad ( 7 )$$

TABLE 2
Energy Budget Ŵ_{B}

| | |
|---|---|
| Inward boundary loss | −Ŵ_{F} |
| Propagation loss | −(1 − Ŵ_{F})η |
| Outward boundary loss | −(1 − η)(1 − Ŵ_{F})W_{F} |
| Energy deficit Ŵ_{B} | −η − Ŵ_{F} − Ŵ_{F}(1 − 2η − Ŵ_{F}) + o(ηŴ_{F}²) |

where the term

$$o ( {\hat{W}}_{F}^{2} )$$

indicates that terms of order

$${\hat{W}}_{F}^{2}$$

are very small and are discarded. Finally, in terms of the loss factor, the imaginary part of the refractive index is

$${n}_{i} = \frac{1}{2} η \frac{c}{( 2 L {ω}_{0} )} . \qquad ( 8 )$$

### Results

For each foam material and with the MRP at the front surface, five one port S₁₁ measurements were made of the material on the metal plate, and five measurements of the plate alone absent the material. The measurements were then repeated with the MRP at the back metal interface. Table 3 summarizes the data averages and measurement standard deviations for the pulse timings used to compute the real part of the refractive index. Table 4 summarizes the data averages and measurement standard deviations for the energy calculation for the imaginary component of the index. The uncertainties in the derived refractive indices were estimated by propagating errors through the calculation equations.

### DISCUSSION

The refractive indices of polystyrene and polyethylene foams were measured in E-band to establish them as suitable materials for support structures for image quality objects.

TABLE 3
Real part of index and associated real permittivity
based on time of flight calculation

| Material | t_{mat\|F} (ps) | t_{air\|F} (ps) | t_{mat\|B} (ps) | nᵣ (Eq. 1) | nᵣ (Eq. 2) | ϵᵣ |
|---|---|---|---|---|---|---|
| XLPE (3 lb) | 514.4(3) | 499.1(3) | 15.1(1) | 1.031(1) | 1.0304(2) | 1.0304(2) |
| CCPS (1 lb) | 510(2) | 505.(2) | 4.18(4) | 1.009(5) | 1.0083(1) | 1.0082(1) |
| CCPS (3 lb) | 521(2) | 507(2) | 14.3(1) | 1.029(7) | 1.0283(3) | 1.0283(3) |

TABLE 4
Imaginary part of index and associated loss terms based on energy analysis

| Material | Ŵ_{F} | Ŵ_{B} | nᵢ (Eq. 8) | α (cm⁻¹) | ∈ᵢ |
|---|---|---|---|---|---|
| XLPE (3 lb) | 0.00019(1) | 0.78(2) | 0.00047(5) | 0.015(2) | 0.0010(5) |
| CCPS (1 lb) | 0.00016(5) | 0.98(1) | 0.00005(2) | 0.0014(5) | 0.00009(5) |
| CCPS (3 lb) | 0.0033(3) | 0.969(6) | 0.00006(1) | 0.0018(4) | 0.00012(6) |

The permittivities of the materials ranged from 1.016 to 1.061 in magnitude, which meet the informative specification of the IEEE N 42.59 standard. The front surface reflected energy of the XLPE (3 lb) and CCPS (3 lb) were computed to be less than 0.02%. The CCPS foams of both densities were extremely low loss; the most transparent material was CCPS (1 lb) with a measured attenuation constant a=0.0016 cm⁻¹.

The measured values of refractive index of the foam materials can be compared with values derived from permittivity models of mixtures; based on solid plastic materials and air, the Landau, Lifshitz, and Looyenga (LLL) formula provides:

$${ϵ}_{\vert foam \vert} = {[ \frac{( {( {ϵ}_{[ soIid ]} )}^{\frac{1}{3}} - 1 ) {ρ}_{[ foam ]}}{{ρ}_{[ solid ]}} + 1 ]}^{3} \qquad ( 9 )$$

The real permittivities of the solid high density polyethylene and polystyrene have known values 2.306 and 2.53, and loss tangents, 3×10⁻⁴ and 7×10⁻⁴, respectively. The volume fraction of the foam is computed from the mass density P [foam] relative to the solid material, for which P [solid] is 1,060 kg/m³ for solid polystyrene and 961 kg/m³ 187 for solid polyethylene. The results extrapolated to the foams are given in Table 5. The real index measured for the materials is consistent with the LLL mixing formula; in particular, the two CCPS materials in Table 3 vary proportionally to density. However, the measured imaginary components of the index in Table 4 are not well-predicted from LLL mixing, which may suggest structural aspects of the foam affect reflection loss, such as by scattering or through localized field enhancements. For example, if scattering dispersed 1.7% of the incident energy, the dielectric loss would be accounted for at the predicted values in Table 5 for the CCPS foams. Angular studies of reflection measured scattering on the order of 1.1% for EPS foams with density 120 kg/m³. Without regard to scattering loss, the imaginary component of the refractive index given in this work is an upper bound. Although the calibration process for these measurements would not allow varying the angle of incidence, scattering could be explored and possibly quantified in future experiments by varying the slab thickness.

TABLE 5
Index predicted from LLL mixing formula

| Material | Volume fraction | Real index, nᵣ | Imaginary Index, nᵢ |
|---|---|---|---|
| XLPE (3 lb) | 0.0499 | 1.024 | 0.000010 |
| CCPS (1 lb) | 0.0151 | 1.008 | 0.000007 |
| CCPS (3 lb) | 0.0453 | 1.025 | 0.000022 |

The analysis of propagation constants applied with this work used temporal pulses reconstructed from E band frequency reflection data to accurately measure the range in time of reflections on the material interfaces. The experiment achieved a time domain range resolution on the order of 0.1 ps or better based on the standard deviation of the measurement of reflection peaks. This is substantially better than the bandpass impulse response resolution, 1.95/[frequency span] ˜ 65 ps associated with the ability to resolve two closely-spaced signals. The time domain range resolution, which is the ability to locate a single response in time, can be much less than the impulse response. In the VNA, the range resolution is set by the number of points on the display. In practice, the time separation of points is reduced by artificially expanding the frequency domain. The enhanced resolution in range is acquired through phase correlation among the sampled frequencies; a perturbation analysis of the superposition of waves at the reflection surface shows that the range resolution is ultimately limited by the uncertainty AS in the reflection magnitude,

$$δ x = \frac{Δ S}{S} \frac{c}{{ω}_{[ band ]}} \qquad ( 10 )$$

where ω_{[band]} is the band center frequency. Using±0.02 in the reflection magnitude tracking error for the uncertainty in S, the time domain range resolution can be expected to be δx/C˜0.1 ps, as achieved in this study. High time resolution for impulse-like reflections is also known to be accomplished by parametric methods using frequency-domain data without Fourier conversion to the time domain.

For the measured materials, the reflected energy from the front surface was negligible in the energy budget. However, the method presented here can be applied to measure absorption in higher refractive index materials that have significant front surface reflection. In this case, the energy from additional internal reflections, which are also included in the formalism, will factor into the energy budget. An interesting example for future work would be a solid low loss plastic material with known permittivity, such as Rexolite, to determine how well the energy loss can be measured in reflection using the time domain, dual calibration technique.

### Condusion

The refractive indices of several structural foam materials made from XLPE and CCPS were measured at E-band frequencies (60-90 GHz). The data demonstrate that the foams have very low reflectivity to millimeter waves, and will not be visible during imaging unless the imaging system has sensitivity better than-42 dB. The results validate the use of the structural foam materials to support image-quality test targets for AIT systems without interfering with the measurement of performance metrics.

The refractive indices were measured in reflection. An interesting aspect to this work is that the measurements were performed in the time domain. The measurements required precision in timing to measure the speed of light in the material, and an analytical framework to evaluate dielectric loss in the material. The method employs a unique dual calibration technique to accomplish the measurement of loss.

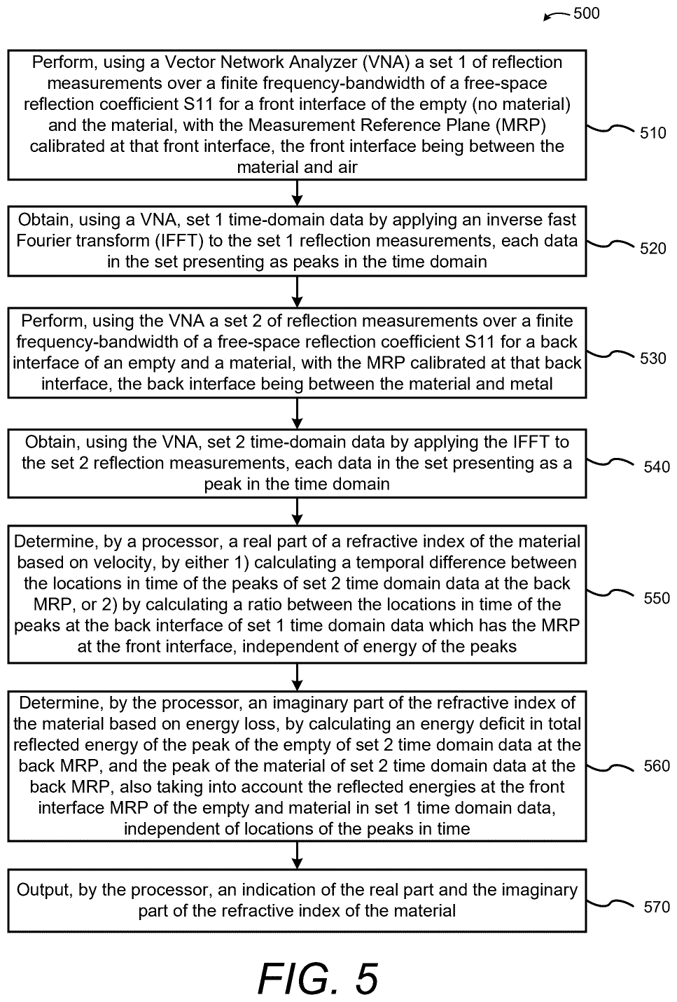

FIG. 5 illustrates a flowchart 500 to determine a refractive index according to an embodiment. At 510, a Vector Network Analyzer (VNA) performs a set 1 of reflection measurements over a finite frequency-bandwidth of a free-space reflection coefficient S₁₁ for a front interface of the empty (no material) and the material, with the Measurement Reference Plane (MRP) calibrated at that front interface, the front interface being between the material and air. At 520, a VNA obtains set 1 time-domain data by applying an inverse fast Fourier transform (IFFT) to the set 1 reflection measurements, each data in the set presenting as peaks in the time domain. At 530, the VNA performs a set 2 of reflection measurements over a finite frequency-bandwidth of a free-space reflection coefficient S₁₁ for a back interface of an empty and a material, with the MRP calibrated at that back interface, the back interface being between the material and metal. At 540, the VNA obtains set 2 time-domain data by applying the IFFT to the set 2 reflection measurements, each data in the set presenting as a peak in the time domain. At 550, a processor determines a real part of a refractive index of the material based on velocity, by either 1) calculating a temporal difference between the locations in time of the peaks of set 2 time domain data at the back MRP, or 2) by calculating a ratio between the locations in time of the peaks at the back interface of set 1 time domain data which has the MRP at the front interface, independent of energy of the peaks. At 560, the processor determines an imaginary part of the refractive index of the material based on energy loss, by calculating an energy deficit in total reflected energy of the peak of the empty of set 2 time domain data at the back MRP, and the peak of the material of set 2 time domain data at the back MRP, also taking into account the reflected energies at the front interface MRP of the empty and material in set 1 time domain data, independent of locations of the peaks in time. At 570, the processor outputs an indication of the real part and the imaginary part of the refractive index of the material.

While a number of example embodiments of the present subject matter have been described, it should be appreciated that the present subject matter provides many applicable inventive concepts that can be embodied in a wide variety of ways. The example embodiments discussed herein are merely illustrative of ways to make and use the subject matter and are not intended to limit the scope of the claimed subject matter. Rather, as will be appreciated by one of skill in the art, the teachings and disclosures herein can be combined or rearranged with other portions of this disclosure and the knowledge of one of ordinary skill in the art.

Terms and phrases used in this document, unless otherwise expressly stated, should be construed as open ended as opposed to closed—e.g., the term “including” should be read as meaning “including, without limitation” or the like; the term “example” is used to provide example instances of the item in discussion, not an exhaustive or limiting list thereof; the terms “a” or should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Furthermore, the presence of broadening words and phrases such as “one or more,” “at least,” “but not limited to,” or other similar phrases, should not be read to mean that the narrower case is intended or required in instances where such broadening phrases may be absent. A ny headers used are for convenience and should not be taken as limiting or restricting. Additionally, where this document refers to technologies that would be apparent or known to one of ordinary skill in the art, such technologies encompass those apparent or known to the skilled artisan now or at any time in the future.

What is claimed is:

1. A system that extracts a complex permittivity of a material, comprising:
a Vector Network Analyzer (VNA) that performs a set 1 of reflection measurements over a finite frequency-bandwidth of a free-space reflection coefficient S₁₁ for a front interface of the empty (no material) and the material, with the Measurement Reference Plane (MRP) calibrated at that front interface, the front interface being between the material and air;
the VNA configured to obtain set 1 time-domain data by applying an inverse fast Fourier transform (IFFT) to the set 1 reflection measurements, each data in the set presenting as peaks in the time domain;
the VNA configured to perform a set 2 of reflection measurements over a finite frequency-bandwidth of a free-space reflection coefficient S₁₁ for a back interface of an empty and a material, with the MRP calibrated at that back interface, the back interface being between the material and metal;
the VNA configured to obtain set 2 time-domain data by applying the IFFT to the set 2 reflection measurements, each data in the set presenting as a peak in the time domain;
a processor that determines a real part of a refractive index of the material based on velocity, by either 1) calculating a temporal difference between the locations in time of the peaks of set 2 time domain data at the back MRP, or 2) by calculating a ratio between the locations in time of the peaks at the back interface of set 1 time domain data which has the MRP at the front interface, independent of energy of the peaks; and
the processor configured to determine an imaginary part of the refractive index of the material based on energy loss, by calculating an energy deficit in total reflected energy of the peak of the empty of set 2 time domain data at the back MRP, and the peak of the material of set 2 time domain data at the back MRP, also taking into account the reflected energies at the front interface MRP of the empty and material in set 1 time domain data, independent of locations of the peaks in time.

2. The system of claim 1, the VNA further configured to perform a first calibration to provide a measurement reference plane (MRP) at a front surface and a second calibration to provide a MRP at a back surface of the material, by moving a translation stage until a reflection signal peak is within an arbitrarily small time of the reflection peak maximum (t=0) to ensure sufficient accuracy for the data required.

3. The system of claim 2, wherein the arbitrarily small time is 0.1 ps to 0.2 ps.

4. The system of claim 1, the translation stage being configured to be raised or lowered to maintain the MRP at the front surface of the material for different locations across the material and for varied materials.

5. The system of claim 1, the VNA being further configured to apply the IFFT to achieve a transformation providing a smaller or larger window around the first reflection and the second reflection of the respective front interface and back interface at smaller or larger intervals, based on a number of measured points.

6. The system of claim 5, wherein the smaller or larger window is 300 ps wide, and the smaller or larger intervals are 0.1 ps.

7. The system of claim 1, the VNA being further configured to use a resolution for a time domain reflection coefficient, based on a maximum value of the load reflection in the temporal band that is small enough to provide sufficient resolution to the data required.

8. The system of claim 7, wherein the temporal band is 2.38×10⁻⁵.

9. The system of claim 1, the processor being configured to model a signal pulse of the time domain peaks as a Gaussian function to determine energy absorbed corresponding to the energy loss.

10. The system of claim 1, the processor being configured to determine the energy loss based in part on applying energy integrals in the time domain in two parts on intervals sufficient to capture a significant area under the curves at a front surface measurement reference plane (MRP) and a back surface MRP.

11. The system of claim 10, wherein the energy integrals are applied in the time domain in two parts on intervals of ±0.15 ns.

12. The system of claim 1, the processor being configured to calculate an energy deficit in total reflected energy intensity of the time domain peaks by performing energy integrals sufficient to capture a significant area under the curves at the front and back surface reference planes using the respective MRPs.

13. The system of claim 12, wherein the energy integrals are performed in the time domain in two parts on intervals of ±0.15 ns.

14. The system of claim 1, the processor being configured to calculate the temporal attributes at least in part by determining differences between times-of-flight of the signals with and without the material present.

15. The system of claim 1, the processor being configured to calculate the temporal attributes at least in part by determining ratios between times-of-flight of the signals with and without the material present.

16. The system of claim 1, the processor being configured to reconstruct temporal pulses from E band reflection data to perform the first set of reflection measurements and the second set of reflection measurements.

17. A method for extracting a complex permittivity of a material, comprising:
performing, using a Vector Network Analyzer (VNA), a set 1 of reflection measurements over a finite frequency-bandwidth of a free-space reflection coefficient S₁₁ for a front interface of the empty (no material) and the material, with the Measurement Reference Plane (MRP) calibrated at that front interface, the front interface being between the material and air;
obtaining, using a VNA, set 1 time-domain data by applying an inverse fast Fourier transform (IFFT) to the set 1 reflection measurements, each data in the set presenting as peaks in the time domain;
performing, using the VNA, a set 2 of reflection measurements over a finite frequency-bandwidth of a free-space reflection coefficient S₁₁ for a back interface of an empty and a material, with the MRP calibrated at that back interface, the back interface being between the material and metal;
obtaining, using the VNA, set 2 time-domain data by applying the IFFT to the set 2 reflection measurements, each data in the set presenting as a peak in the time domain;
determining, by a processor, a real part of a refractive index of the material based on velocity, by either 1) calculating a temporal difference between the locations in time of the peaks of set 2 time domain data at the back MRP, or 2) by calculating a ratio between the locations in time of the peaks at the back interface of set 1 time domain data which has the MRP at the front interface, independent of energy of the peaks;
determining, by the processor, an imaginary part of the refractive index of the material based on energy loss, by calculating an energy deficit in total reflected energy of the peak of the empty of set 2 time domain data at the back MRP, and the peak of the material of set 2 time domain data at the back MRP, also taking into account the reflected energies at the front interface MRP of the empty and material in set 1 time domain data, independent of locations of the peaks in time; and
outputting, by the processor, an indication of the real part and the imaginary part of the refractive index of the material.

18. The method of claim 17, further comprising performing a first calibration to provide a measurement reference plane (MRP) at a front surface of the material, and a second calibration to provide a MRP at a back surface of the material, by moving a translation stage until a reflection signal peak is within an arbitrarily small time of the reflection peak maximum (t=0) to ensure sufficient accuracy for data required.

19. The method of claim 17, further comprising determining the energy loss based in part on applying energy integrals in the time domain in two parts on intervals sufficient to capture a significant area under the curves at a front surface measurement reference plane (MRP) and a back surface MRP.

20. The method of claim 17, wherein calculating an energy deficit in total reflected energy intensity of the time domain peaks comprises performing energy integrals sufficient to capture a significant area under the curves at the front and back surface reference planes using the respective MRPs.
